(19) United States
(12) Patent Application Publication
(10) Pub. No.: US 2025/0334617 A1
(43) Pub. Date: Oct. 30, 2025

(54) VIRTUAL ESTIMATION OF THE TEMPERATURE OF A CURRENT TRANSFORMER

(71) Applicant: SAGEMCOM ENERGY & TELECOM SAS, BOIS-COLOMBES (FR)

(72) Inventors: Henry TEBOULLE, BOIS-COLOMBES (FR); Lucas LEBAILLY, BOIS-COLOMBES (FR); Fabien DE LA CRUZ, BOIS-COLOMBES (FR)

(21) Appl. No.: 19/188,594

(22) Filed: Apr. 24, 2025

(30) Foreign Application Priority Data
Apr. 24, 2024 (FR) FR2404221

(51) Int. Cl. G01R 22/06; G01K 7/42; G01R 19/165; G01R 19/32

(52) U.S. Cl. CPC G01R 22/061; G01K 7/42; G01R 19/16538; G01R 19/32

(57) ABSTRACT

An electricity meter includes a current transformer arranged to produce first measurements of a current flowing in a winding of the current transformer; a temperature sensor; and a processing unit arranged to evaluate an estimated current and an internal temperature, to evaluate an estimated temperature of the winding on the basis of the estimated current and internal temperature, and to evaluate, on the basis of the estimated temperature, a measurement phase offset produced by the current transformer on the first measurements, the measurement phase offset being intended to be used to measure the electrical energy consumed.

The invention relates to electricity meters integrating at least one current transformer.

### BACKGROUND

An electricity meter measures the electrical energy supplied by a distribution network (polyphase or single-phase) to an installation. To measure the electrical energy available, measurements must be taken of the current(s) supplied to the installation in question. In order to measure the current(s), it is common to integrate one or all of the internal current transformers into the meter.

The level of precision required to measure the electrical energy consumed by the installation is very stringent: 0.5%, even up to 0.2% or 0.1%. In particular, this requirement must be met during self-heating tests of current transformers.

It is known that a current transformer generates a phase offset Δφ(t) on the current measurements, which, if not compensated, causes a significant inaccuracy in measuring the energy consumed. This inaccuracy makes it impossible to maintain the precision classes which have just been mentioned.

The phase offset Δφ(t) depends on the temperature of the current transformer r windings, and, in particular, on the temperature of the secondary winding in which the image of the current supplied to the installation flows. It is thus necessary to accurately estimate the temperature of the winding. This makes it possible to obtain a precise estimate of the phase offset Δφ(t), and thus to effectively compensate this phase offset to obtain a sufficiently precise measurement of the energy consumed.

A temperature sensor is conventionally integrated into the meter box. For example, it is an NTC-type thermistor (NTC stands for Negative Temperature Coefficient). The most obvious solution thus consists in using this temperature measurement to estimate the phase offset Δφ(t).

However, experience shows that the temperature decreases very quickly as it moves away from the windings of the transformers and that, even if the thermistor is close to the windings, it does not accurately reflect the temperature of the windings. The estimate obtained of the winding temperature is thus too imprecise to maintain the mentioned accuracy classes.

It has thus been envisaged to mount a temperature sensor directly on each transformer. This solution generates a certain additional cost and a certain design complexity, especially in polyphase meters (integrating a number of temperature sensors equal to the number of transformers). Furthermore, the windings of the transformers are integrated in a plastic sheath. The positioning of the temperature sensor on the plastic sheath thus provides a very inaccurate evaluation of the actual temperature of the windings.

### AIM

The invention aims to evaluate the phase offset in the current measurements caused by a current transformer integrated in an electricity meter in a precise, simple and inexpensive manner.

### SUMMARY

In view of achieving this aim, an electricity meter is proposed, arranged to measure the electrical energy supplied to an installation by a distribution network, the electricity meter comprising:
a device for measuring the current, comprising a current transformer, and arranged to produce first measurements representative of a current flowing in a winding of the current transformer;
A temperature sensor, arranged to produce second measurements representative of the internal temperature present inside the meter;
a processing unit arranged to:
   evaluate an estimated current on the basis of the first measurements, and the internal temperature on the basis of the second measurements;
   evaluate an estimated temperature of the winding on the basis of the estimated current and the internal temperature;
   evaluate, on the basis of the estimated temperature, a measurement phase offset produced by the current transformer during the first measurements, the measurement phase offset being intended to be used to measure said electrical energy.

By using both the internal temperature present inside the meter, and also the estimated current that is evaluated from the first measurements produced by the current measuring device, the processing unit is capable of evaluating the current transformer winding temperature very accurately and in real time. The processing unit may thus evaluate the measurement phase offset very precisely, and thus produce a very precise estimate of the energy consumed by the installation. The drastic precision requirements to measure the electrical energy consumed are reached. This way of estimating the temperature of the winding does not require any additional hardware (material) component, and is thus very simple and inexpensive to implement.

In addition, an electricity meter is proposed as described above wherein the processing unit is arranged to apply a low-pass filter during the first measurements to obtain the estimated current.

In addition, an electricity meter, such as described above is proposed, in which the low-pass filter is a first-order Butterworth filter.

In addition, an electric meter as described above is proposed, in which the estimated temperature is evaluated from the estimated current squared.

In addition, an electricity meter is proposed as described above, comprising a plurality of current measuring devices each comprising a current transformer, the processing unit being arranged, for each current transformer, to evaluate the estimated temperature of a winding of said current transformer on the basis of:
the internal temperature;
the estimated current for said current transformer; and
also using an approximate temperature of a winding of at least one other current transformer, the approximate temperature of the winding of the at least one other current transformer being evaluated on the basis of the internal temperature and the estimated current for the at least one other current transformer.

In addition, an electricity meter is proposed, wherein the at least one other current transformer comprises the current transformer positioned closest to said current transformer.

In addition, an electricity meter is proposed, wherein the electricity meter comprises a first current measuring device comprising a first current transformer and arranged to measure a current flowing on a first phase, a second current measuring device comprising a second current transformer and arranged to measure a current flowing on a second phase, and a third current measuring device comprising a third current transformer and arranged to measure a current flowing on a third phase;
the second current transformer being positioned between the first current transformer and the third current transformer;
the processing unit being arranged to:
   evaluate the estimated temperature of the winding of the first current transformer using also the approximate temperature of the winding of the second current transformer;
   evaluate the estimated temperature of the winding of the second current transformer using also the approximate temperature of the winding of the first current transformer and the approximate temperature of the winding of the third current transformer;
   evaluate the estimated temperature of the winding of the third current transformer using also the approximate temperature of the winding of the second current transformer.

In addition, an electricity meter is proposed, the electricity meter being a single-phase meter comprising a single current measuring device, comprising a current transformer and arranged to measure a current flowing on a neutral.

There is also provided an electricity meter as described above, wherein:
the current transformer(s) are positioned in a first side of the electricity meter, either the left-hand and right-hand side, and in a first portion of a top portion and a bottom portion of the electricity meter;
the temperature sensor is positioned in a second side and in a second portion of the electricity meter.

There is also provided a measuring method performed in a processing unit of an electricity meter as described above and comprising the steps of:
evaluate an estimated current on the basis of the first measurements, and the internal temperature on the basis of the second measurements;
evaluate an estimated temperature of the winding on the basis of the estimated current and the internal temperature;
evaluate, on the basis of the estimated temperature, a measurement phase offset produced by the current transformer during the first measurements, the measurement phase offset being intended to be used to measure said electrical energy.

In addition, a computer program is proposed, comprising instructions which lead to the processing unit of the electricity meter such as described above, executing the steps of the measuring method such as described above.

Also proposed is a computer-readable storage medium on which the previously described computer program is stored.

The invention will be best understood in the light of the following description of particular non-limiting embodiments of the invention.

### BRIEF DESCRIPTION OF THE DRAWINGS

Reference will be made to the accompanying drawings, among which:

FIG. 1 diagrammatically shows an electric meter, and also shows the calibration of the meter measuring module;

FIG. 2 is a simplified front view of the meter, without the cover that closes the meter box;

FIG. 3 is a graph comprising a curve of the temperature (in ° C.) of a winding of a current transformer as a function of time, and a curve of the current (in A) flowing through the winding as a function of time.

### DETAILED DESCRIPTION

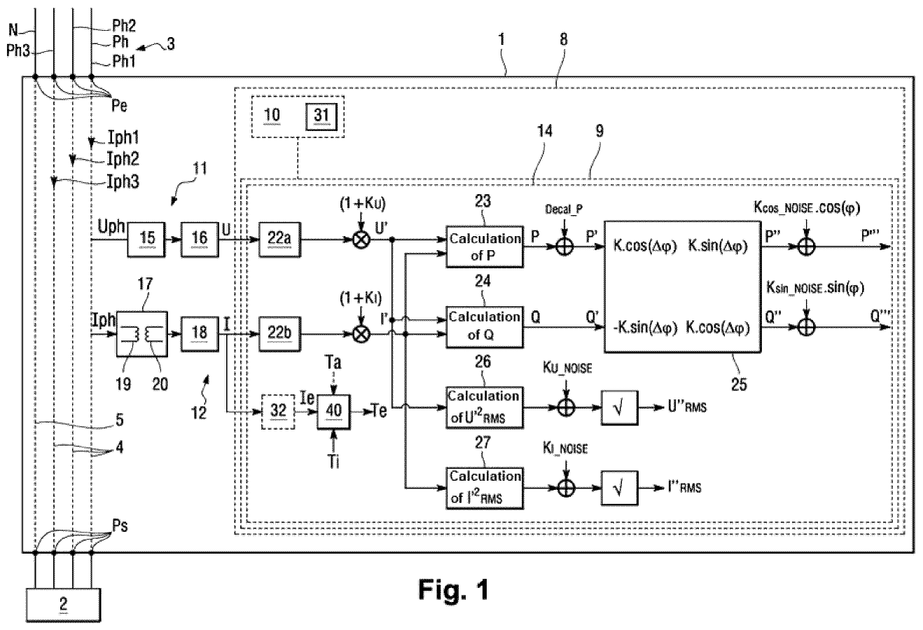

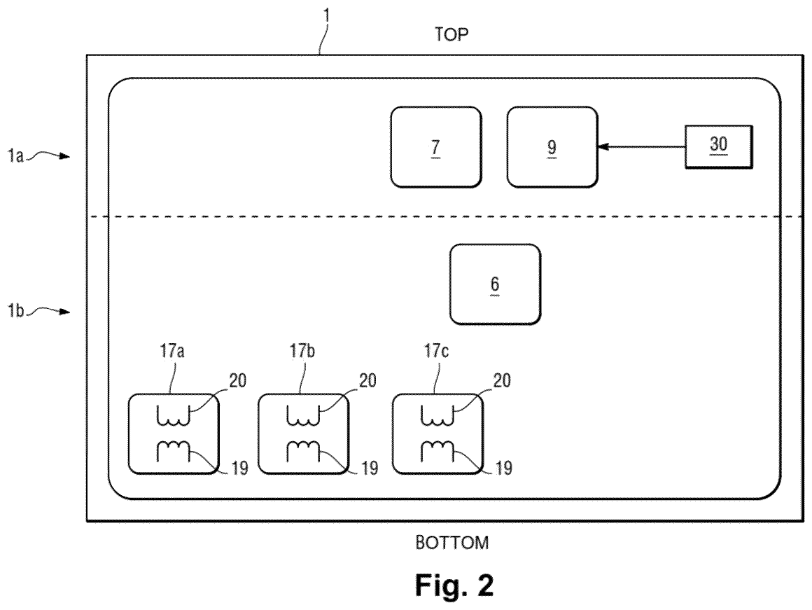

With reference to FIGS. 1 and 2, the electricity meter 1 is, in this case, is a three-phase meter intended to measure the energy supplied to the electrical installation 2 of a subscriber by a distribution network 3.

The distribution network 3 comprises three phase lines (Ph1, Ph2 and Ph3), and a neutral N.

The meter 1 comprises three input ports Pe each connected to one of the phases Ph of the distribution network 3, and an input port Pe connected to the neutral N. The meter 1 also comprises four output ports Ps connected to the installation 2 (three for the phases and one for the neutral).

The meter 1 comprises three phase conductors 4 each connected to one of the phases Ph, and a neutral conductor 5 connected to neutral N.

The meter 1 also includes a cut-off member 6 (visible in FIG. 2) comprising, for each phase Ph, a switch mounted on the associated phase conductor 4. The cut-off member 6 is used in particular for remotely interrupting or re-establishing the supply of power to the installation 2, e.g., in the event of the subscription being cancelled or of the subscription contract not being complied with.

The meter 1 comprises an “applicational” portion and a “metrological” portion.

The applicational portion and an applicational micro-controller 7 that, in particular, operates the cut-off member 6.

The metrological portion comprises a processing unit 8 (electronic and software). The processing unit 8 comprises at least one processing component 9, which is, for example, a “general” processor, a processor specialising in the processing of the signal (or DSP, for Digital Signal Processor), a micro-controller, or a programmable logic circuit, such as an FPGA (for Field-Programmable Gate Array) or an ASIC (for Application-Specific Integrated Circuit). The processing unit 8 also comprises one or more memories 10, connected to the processing component 9, or integrated in the processing component 9. At least one of the memories 10 forms a computer-readable medium storing at least one computer program including instructions enabling the processing unit 8 to execute the steps of the measuring method that is described below.

In this case, the processing unit 8 also comprises a metrological micro-controller, 9. The measurement process is implemented in the metrological micro-controller 9.

In addition to the processing unit 8, the metrological portion comprises, for each phase Ph of the distribution network 3, a voltage measuring device 11, a current measuring device 12, and a measuring module 14. In FIG. 1, the elements 11, 12, 14 (and their components) are shown for a phase Ph only, but the meter 1 comprises such elements for each of the phases Ph.

The voltage measuring device 11 comprises resistors 15 forming a voltage divider bridge, and a voltage measuring chain 16. The voltage divider bridge makes it possible to produce, on the basis of the voltage UPH of the phase Ph of the network 3, a voltage less than or equal to 3.3 V. The voltage measuring chain 16 comprises an analogue-to-digital converter. The voltage measuring chain 16 produces measurements of the phase voltage UPH present during the associated phase Ph.

The current measuring device 12 comprises a current transformer 17 and a current measuring chain 18 connected to the current transformer 17.

The current transformer 17 comprises a primary winding 19 in which the phase current Iph flows, and a secondary winding 20.

Each winding 19, 20 may comprise any number of turns.

The primary winding 19 is preferably the phase conductor 4 itself, and thus comprises, in this case, only one turn. The transformer 17 is thus, for example, an opening current transformer constituting a core on which the secondary winding is wound in the form of turns all along the core through which the phase conductor 4 passes. This may also be a Rogowski sensor.

The current measuring chain 18 preferably comprises a resistor followed by an analogue-to-digital converter, connected to the secondary winding 20 of the current transformer 17, and any additional electronic components which may comprise one or more amplifiers. The current measuring chain 18 produces first measurements representative of the current flowing in the primary winding and supplied to the installation 2. It is thus the phase current Iph flowing on phase Ph.

In the meter, there is thus a first current transformer 17a used to measure the first phase current Iph1, a second current transformer 17b used to measure the second phase current Iph2, and a third current transformer 17c used to measure the third phase current Iph3.

The measuring module 14 is a digital module that is implemented in the metrological micro-controller 9 of the meter 1. The measuring module 14 is connected to the voltage measuring chain 16 and to the current measuring chain 18.

The measuring module 14 comprises, in the case of fundamental measurements, low-pass filters 22a, 22b arranged to eliminate any harmonics of the phase voltage and of the phase current so as to produce a fundamental phase voltage and a fundamental phase current. In the case of measurements with harmonics, the low-pass filters 22a and 22b are eliminated.

The measuring module 14 further comprises a plurality of calculation modules, which make it possible to evaluate the active power, reactive power, RMS voltage (this stands for the Root Mean Square; this is the effective value) and the RMS current distributed by the distribution network 3 via the phase Ph.

For each phase Ph, the measurement of these magnitudes makes it possible to evaluate the electrical energy supplied to the installation 2 by the distribution network 3.

The measuring module 14 uses a certain number of calibration parameters to perform these calculations. These calibration parameters are as follows: K_{U}, K_{I}, Decal_P, K_{U_NOISE}, K_{I_NOISE}, K_{COS_NOISE}·cos(φ), K_{SIN_NOISE}·sin(φ), K, Δφ.

The phase voltage U is multiplied by a multiplying factor integrating the voltage parameter K_{U}, to obtain a compensated voltage U′. The multiplying factor is equal to (1+K_{U}).

The phase current I is multiplied by a multiplying factor integrating the current parameter K_{I}, to obtain a compensated current I′. The multiplying factor is equal to (1+K_{I}).

The module 23 acquires the compensated voltage U′ and the compensated current I′ and produces a raw active power P.

The parameter Decal_P is added to the raw active power P to obtain an active power P′.

The module 24 acquires the compensated voltage U′ and the compensated current I′ and produces a raw reactive power Q.

Module 25 that is in the form of a matrix, acquires the active power P′ and the reactive power Q′ (in this case, equal to Q) and evaluates the compensated active power P″ and the compensated reactive power Q″, by calculating:

$${P}^{″} = K . cos ( Δφ ) . {P}^{′} + K . sin ( Δφ ) . {Q}^{′}$$

$${Q}^{″} = - K . sin ( Δφ ) . {P}^{′} + K . cos ( Δφ ) . {Q}^{′}$$

The parameter K_{COS_NOISE}·cos(φ) is added to the compensated active power P″ to obtain the active power P″.

The parameter K_{SIN_NOISE}·sin(φ) is added to the compensated reactive power Q″ to obtain the reactive power Q″.

Module 26 acquires the compensated voltage U′ and calculates the RMS voltage squared:

$${U}_{R M S}^{′2} .$$

The parameter K_{U_NOISE} is added to the RMS voltage squared, then the root of the result of this addition is calculated, to obtain the compensated RMS voltage

$${U}_{R M S}^{″} .$$

Module 27 acquires the compensated current and calculates the RMS current squared:

$${I}_{R M S}^{′2} .$$

The parameter K_{I_NOISE} is added to the RMS current squared, then the root of the result of this addition is calculated, to obtain the compensated RMS current

$${I}_{R M S}^{″} .$$

The calibration parameters used by the measuring module 14 make it possible, in particular, to compensate for the variations in gain on the phase voltage due to the components of the voltage measuring chain 16, the variations in gain on the phase current due to the components of the current measuring chain 18, the effects of white noise intrinsic to the meter 1, the quantisation noise of the analogue-digital converter of the voltage measuring chain 16 and of the analogue-digital converter of the current measuring chain 18, the gain variations of the voltage measuring chain 16 and the current measuring chain 18, etc.

Calibration parameters starting with “K” as well as Decal_P are fixed and calibrated at the factory.

The calibration parameter Δφ(t), itself, makes it possible to compensate for the phase variations of the current measuring chain 18, due to the current transformer 17.

It is thus a measurement phase offset produced by the current transformer 17 on the first measurements, which are produced by the current measuring device 12 and which are representative of the phase current Iph supplied to the installation 2 and flowing in the primary winding 19 of the current transformer 17.

This measurement phase offset Δφ(t) is variable and is not calibrated at the factory. This depends on the temperature of winding 20 of current transformer 17.

The measurement phase offset Δφ(t) is estimated in real time by the processing unit 8 of the meter 1.

The meter 1 integrates a temperature sensor 30 that, in this case, is an NTC-type thermistor. The thermistor 30 is connected to the metrological micro-controller 9 of the processing unit 8. The thermistor 30 produces the second measurements representative of the internal temperature present inside the meter;

For each current transformer 17, the processing unit 8 will thus evaluate the measurement phase offset Δφ(t), as follows.

The processing unit 8 firstly evaluates an estimated current Ie on the basis of the first measurements (produced by the current measuring device 12), and the internal temperature Ti present in the meter 1 on the basis of the second measurements (produced by the thermistor 30).

Then, a calculation module 40 of the measuring module 14 of the processing unit 8 evaluates an estimated temperature Te of the secondary winding 20 on the basis of the estimated current Ie and the internal temperature Ti. The processing unit 8 then evaluates the measurement phase offset Δφ(t), produced by the current transformer 17 on the first measurements, on the basis of the estimated temperature of the secondary winding 20 of the current transformer 17. The measurement phase offset is intended, as has been seen, to be used to measure the electrical energy supplied to the installation 2 by the distribution network 3.

The measurement phase offset Δφ(t) may be deduced from the estimated temperature of the secondary winding 20 on the basis of the manufacturer data of the transformer 17. The cross-reference table 31 is, for example, stored in one of the memories 10 of the processing unit 8. This correspondence table 31 associates phase offset values with temperature values of the secondary winding 20.

In a first embodiment, the estimated current Ie is the current I that corresponds to the first measurements produced by the measuring device 12. The estimated temperature of the winding is, for example, evaluated on the basis of the estimated current squared; an analogy is used with the heat dissipation of a resistor in RI².

For example:

$$TC 1 ( t ) = C T N ( t ) + K 1. I 1 {( t )}^{2}$$

$$TC 2 ( t ) = C T N ( t ) + K 2. I 2 {( t )}^{2}$$

$$TC 3 ( t ) = C T N ( t ) + K 3. I 3 {( t )}^{2}$$

in which TC1(t) is the estimated temperature (in real time) of the secondary winding 20 of the first transformer 17a of the first phase Ph1, I1(t) is the estimated current for the first transformer 17a, K1 is a fixed factor determined by design, and CTN(t) is the internal temperature;
in which TC2(t) is the estimated temperature (in real time) of the secondary winding 20 of the second transformer 17b of the second phase Ph2, I2(t) is the estimated current for the second transformer 17b, K2 is a fixed factor determined by design, and CTN(t) is the internal temperature;
and in which TC3(t) is the estimated temperature (in real time) of the secondary winding 20 of the third transformer 17c of the third phase Ph3, I3(t) is the estimated current for the third transformer 17c, K3 is a fixed factor determined by design, and CTN(t) is the internal temperature.

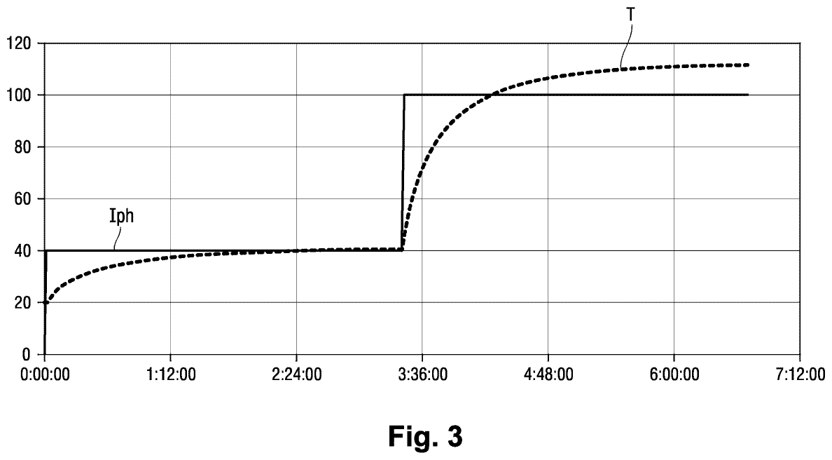

FIG. 3 shows the manner in which the actual temperature T of the secondary winding 20 of a current transformer 17 varies, while a phase current Iph firstly zero, then equal to 40 A, then equal to 100 A, flows in the primary winding 19. This FIG. 3 has been obtained during self-heating tests of current transformers 17. A certain delay is necessary for the temperature of the winding to reach a constant level corresponding to the applied level of current (approximately 40° C. for the level 40 A and approximately 112° C. for level 100 A).

In a second embodiment, the estimated current Ie, on the basis of which the measurement phase offset is evaluated Δφ(t), is no longer directly the current corresponding to the first measurements. This time, to take into account the transitional phases, the processing unit 8 applies a low-pass filter 32 during the first measurements to obtain the estimated current Ie.

The application of the low-pass filter 32 to the current I(t), and whose output is I′(t), makes it possible to smooth the curve to come as close as possible to the reality in which the winding temperature requires a certain time to stabilise. The estimated temperature Te, as a function of time, of the secondary winding 20, obtained by this method, is closer to the actual temperature of the winding.

Thus, the following is obtained:

$$TC 1 ( t ) = C T N ( t ) + K 1. {I}^{′} 1 {( t )}^{2}$$

$$TC 2 ( t ) = C T N ( t ) + K 2. {I}^{′} 2 {( t )}^{2}$$

$$TC 3 ( t ) = C T N ( t ) + K 3. {I}^{′} 3 {( t )}^{2}$$

in which TC1(t) is the estimated temperature (in real time) of the secondary winding 20 of the first transformer 17a of the first phase Ph1, I′1(t) is the estimated current for first transformer 17a (first measurements on which the low-pass filter 32 has been applied), K1 is a fixed factor determined by design, and CTN(t) is the internal temperature;
in which TC2(t) is the estimated temperature (in real time) of the secondary winding 20 of the second transformer 17b of the second phase Ph2, I′2(t) is the estimated current for the second transformer 17b (first measurements on which the low-pass filter 32 has been applied), K2 is a fixed factor determined by design, and CTN(t) is the internal temperature;
and in which TC3(t) is the estimated temperature (in real time) of the secondary winding 20 of the third transformer 17c of the third phase Ph3, I′3(t) is the estimated current for the third transformer 17c (first measurements on which the low-pass filter 32 has been applied), K3 is a fixed factor determined by design, and CTN(t) is the internal temperature.

The low-pass filter 32 used is, for example, a first-order Butterworth filter. The aim is to filter I(Z) so as to obtain at the output of the linear filter H(Z):

$${I}^{′} ( Z ) = I ( Z ) . H ( Z )$$

The Z transform of a first-order Butterworth filter is expressed by the relationship:

$$H ( Z ) = G . \frac{1 + {Z}^{- 1}}{1 - a . {Z}^{- 1}} with Z = {e}^{\frac{j \text{.2} . π . f}{{f}_{E}}}$$

It is assumed that the current I(t) is sampled digitally at the frequency of 1 Hz.

The parameter a is selected such that the rise time is compatible with the design and the gain of the filter is equal to 1.

In this case, a=0.9993606 and G=0.0003197 are selected to have a rise time to 90% of 1 h and a gain of 1.

In a third embodiment, the processing unit 8 evaluates, for each current transformer 17, the estimated temperature Te of the winding 20 of said current transformer 17 on the basis of:
the internal temperature Ti (thermistor 30);
the estimated current Ie for said current transformer; and
Also using an approximate temperature Ta of the secondary winding 20 of at least one other current transformer 17, the approximate temperature Ta of the secondary winding 20 of the at least one other current transformer 17 being evaluated on the basis of the internal temperature Ti and the estimated current Ie for the at least one other current transformer 17.

In this embodiment, the “approximate temperature” thus corresponds to the “estimated temperature” of the preceding embodiments.

The at least one other current transformer comprises the current transformer positioned closest to said current transformer.

In this case, the electricity meter 1 comprises a first current transformer 17a, a second current transformer 17b and a third current transformer 17c.

The transformers 17a, 17b, 17c of the phases Ph1, Ph2 and Ph3 are aligned in this order. FIG. 2 shows the first transformer 17a on the left, the second transformer 17b in the middle of the other two and the third transformer 17c on the right. The second current transformer 17b is thus positioned between the first current transformer 17a and the third current transformer 17c;

It may be considered that the second transformer 17b, when it is traversed by a high current (at least a few tens of amperes), may raise the temperature close to the first transformer 17a and the third transformer 17c.

The first transformer 17a, when it is traversed by a high current, may raise the temperature close to the second transformer 17b. The third transformer 17c, when it is traversed by a high current, may also raise the temperature around the second transformer 17b.

Thus, the processing unit 8:
evaluates the estimated temperature of the secondary winding 20 of the first current transformer (17a) using also the approximate temperature of the secondary winding 20 of the second current transformer (17b);
evaluates the estimated temperature of the secondary winding of the second current transformer 17b using also the approximate temperature of the secondary winding 20 of the first current transformer 17a and the approximate temperature of the secondary winding 20 of the third current transformer 17c;
evaluates the estimated temperature of the secondary winding 20 of the third current transformer 17c using also the approximate temperature of the secondary winding 20 of the second current transformer 17b.

Thus, relative to the formulae previously used, to evaluate the ambient temperature, not only the value of the temperature measured by the thermistor 30 is taken into account, but rather a temperature derived from that of the thermistor 30 and those of the transformers 17.

The approximate temperatures thus continue to be estimated TC1(t), TC2(t) and TC3(t) as before, but the estimated temperatures (in real time) are deduced from that TC′1(t), TC′2(t) and TC′3(t) in the following manner.

In the case of the first transformer 17a, in the formula, the term CTN(t) is replaced by (CTN(t)+TC2(t)/2 and the estimated temperature TC′1(t) is determined, which is such that:

$${TC}^{′} 1 ( t ) = ( C T N ( t ) + TC 2 ( t ) ) / 2 + K 1. {I}^{′} 1 {( t )}^{2}$$

In the case of the second transformer 17b, in the formula, the term CTN(t) is replaced by (CTN(t)+(TC1(t)+TC3(t))/2)/2 and the estimated temperature TC′2(t) is determined, which is such that:

$${TC}^{′} 2 ( t ) = ( C T N ( t ) + ( TC 1 ( t ) + TC 3 ( t ) ) / 2 ) / 2 + K 2. {I}^{′} 2 {( t )}^{2}$$

In the case of the third transformer 17c, in the formula, the term CTN(t) is replaced by (CTN(t)+TC2(t))/2 and the estimated temperature TC′3(t) is determined, such that:

$${TC}^{′} 3 ( t ) = ( C T N ( t ) + TC 2 ( t ) ) / 2 + K 3. {I}^{′} 3 {( t )}^{2}$$

It is then the estimated temperatures TC′1(t), TC′2(t) and TC′3(t) which are taken into account to determine the respective measurement phase offsets Δφ1(t), Δφ2(t) and Δφ3(t).

This embodiment is the preferred three-phase mode, because it is the one that provides the best precision.

The first and second embodiments described apply, of course, in the case of a single-phase meter. Typically, a single-phase meter comprises a single current transformer used to measure the current flowing on the neutral (the phase current preferably being measured by a shunt).

The estimated temperature is such that:

$$T C N ( t ) = C T N ( t ) + KN . {IN ( t )}^{2}$$

In this case, the estimated current IN(t) is obtained directly on the basis of the first measurements produced by the current measuring device that measures the neutral current.

Alternatively, and preferably, the estimated temperature is obtained as follows:

$$T C N ( t ) = C T N ( t ) + K N . {I}^{′} {N ( t )}^{2}$$

In this case, the estimated current I′N(t)² is the current corresponding to the first measurements, to which the low-pass filter 32 has been applied.

We now turn to the positions of the various elements in the meter 1. It is preferable for the thermistor 30 to be positioned in the meter box 1 as far away as possible from the hot points, i.e., in this case, from the current transformer(s) 17 and from the cut-off member 6.

Thus, advantageously:
the current transformer(s) 17 and the cut-off member 6 are positioned in a first side of the box of the electricity meter 1, either the left-hand and right-hand side, and in a first portion of a top portion 1a and a bottom portion 1b of the electricity meter;
the thermistor 30 is positioned in a second side and in a second portion of the electricity meter 1.

The terms “top”, “bottom”, “left”, “right” correspond to a situation in which the meter is positioned in its nominal operating position (in this case, with its rear surface positioned against a vertical support).

The transformer(s) 17 and the cut-off member 6 are preferably positioned in the bottom portion 1b of the electric meter 1, for example, on the left, and the thermistor 30 is preferably positioned in the top portion 1a of the electric meter 1, and thus on the right, in this example.

The current transformer(s) 17 and the cut-off member 6, on the one hand, and the thermistor 30, on the other hand, are preferably located in diagonally opposite portions of the internal volume of the meter 1.

In the case(s) in which the current transformer(s) 17, the cut-off member 6 and the thermistor 30 are mounted on the same electrical board, they are located in diagonally opposite portions of said board.

Naturally, the invention is not limited to the embodiments described, but comprises any variant entering into the scope of the invention such as defined by the claims.

The formulae used may be different from those given above.

For example, the estimated winding temperature of transformer may be estimated from the estimated current cubed rather than squared.

It is possible add the coefficients into all of the formulae.

Any of the following be possible, for example:

$$TC 1 ( t ) = α . C T N ( t ) + K 1. I 1 {( t )}^{2}$$

The meter may be single-phase or three-phase, or, more generally, polyphase.

The estimated temperature, on the basis of which the measurement phase offset is estimated, may be the temperature of a primary winding of the current transformer. In this case, the estimated current, used to evaluate the estimated temperature, is evaluated on the basis of measurements representative of the current flowing in this primary winding.

1. An electricity meter arranged to measure some electrical energy supplied to an installation by a distribution network, the electricity meter comprising:
a device for measuring the current, comprising a current transformer, and arranged to produce first measurements representative of a current flowing in a winding of the current transformer;
a temperature sensor, arranged to produce second measurements representative of the internal temperature present inside the meter;
a processing unit arranged to:
evaluate an estimated current on the basis of the first measurements, and the internal temperature on the basis of the second measurements;
evaluate an estimated temperature of the winding on the basis of the estimated current and the internal temperature;
evaluate, on the basis of the estimated temperature, a measurement phase offset produced by the current transformer during the first measurements, the measurement phase offset being intended to be used to measure said electrical energy.

2. The electricity meter according to claim 1, wherein the processing unit is arranged to apply a low-pass filter during the first measurements to obtain the estimated current.

3. The electricity meter according to claim 2, wherein the low-pass filter is a first-order Butterworth filter.

4. The electricity meter according to claim 1, wherein the estimated temperature is evaluated on the basis of the estimated current squared.

5. The electricity meter according to claim 1, comprising a plurality of current measuring devices each comprising a current transformer, the processing unit being arranged, for each current transformer, to evaluate the estimated temperature of a winding of said current transformer on the basis of:
the internal temperature;
the estimated current for said current transformer; and
also using an approximate temperature of a winding of at least one other current transformer, the approximate temperature of the winding of the at least one other current transformer being evaluated on the basis of the internal temperature and the estimated current for the at least one other current transformer.

6. The electricity meter according to claim 5, wherein the at least one other current transformer comprises the current transformer positioned closest to said current transformer.

7. The electricity meter according to claim 6, wherein the electricity meter comprises a first current measuring device comprising a first current transformer and arranged to measure a current flowing on a first phase, a second current measuring device comprising a second current transformer and arranged to measure a current flowing on a second phase, and a third current measuring device comprising a third current transformer and arranged to measure a current flowing on a third phase;
the second current transformer being positioned between the first current transformer and the third current transformer;
the processing unit being arranged to:
evaluate the estimated temperature of the winding of the first current transformer using also the approximate temperature of the winding of the second current transformer;
evaluate the estimated temperature of the winding of the second current transformer using also the approximate temperature of the winding of the first current transformer and the approximate temperature of the winding of the third current transformer;
evaluate the estimated temperature of the winding of the third current transformer using also the approximate temperature of the winding of the second current transformer.

8. Electricity meter according to claim 1, the electricity meter being a single-phase meter comprising a single current measuring device, comprising a current transformer and arranged to measure a current flowing on a neutral.

9. The electricity meter according to claim 1, wherein:
the current transformer(s) are positioned in a first side of the electricity meter, either the left-hand and right-hand side, and in a first portion of a top portion and a bottom portion of the electricity meter;
the temperature sensor is positioned in a second side and in a second portion of the electricity meter.

10. The measuring method, implemented in the processing unit of the electricity meter according to claim 1, and comprising the following steps to:
evaluate an estimated current on the basis of the first measurements, and the internal temperature on the basis of the second measurements;
evaluate an estimated temperature of the winding on the basis of the estimated current and the internal temperature;
evaluate, on the basis of the estimated temperature, a measurement phase offset produced by the current transformer on the first measurements, the measurement phase offset being intended to be used to measure said electrical energy.

11. (canceled)

12. A non-transitory computer-readable storage medium, on which a computer program is stored, the computer program comprising instructions which lead to the processing unit of the electricity meter according to claim 1 executing a measuring method, implemented in the processing unit of the electricity meter, and the measuring method comprising the following steps to:
evaluate an estimated current on the basis of the first measurements, and the internal temperature on the basis of the second measurements;
evaluate an estimated temperature of the winding on the basis of the estimated current and the internal temperature;
evaluate, on the basis of the estimated temperature, a measurement phase offset produced by the current transformer on the first measurements, the measurement phase offset being intended to be used to measure said electrical energy.
